(19) United States
(12) Patent Application Publication
(10) Pub. No.: US 2025/0248179 A1
(43) Pub. Date: Jul. 31, 2025

(54) MICRO LIGHT-EMITTING DIODE AND DISPLAY APPARATUS HAVING SAME

(71) Applicant: QUANZHOU SANAN SEMICONDUCTOR TECHNOLOGY CO., LTD., Quanzhou (CN)

(72) Inventors: Xueping YE, Xiamen (CN); Te-ling HSIA, Xiamen (CN); Chia-en LEE, Xiamen (CN); Zheng WU, Xiamen (CN)

(21) Appl. No.: 19/182,754

(22) Filed: Apr. 18, 2025

Related U.S. Application Data
(63) Continuation of application No. PCT/CN2022/110617, filed on Oct. 21, 2022.

(51) Int. Cl. H10H 20/831; H01L 25/075; H10H 20/82; H10H 20/825; H10H 20/832; H10H 20/84; H10H 29/24

(52) U.S. Cl. CPC H10H 20/8314; H10H 20/82; H10H 20/825; H10H 20/835; H10H 20/84; H01L 25/0753; H10H 29/24

(57) ABSTRACT

A micro light-emitting diode is provided, which includes a semiconductor layer sequence. A back side of the semiconductor layer sequence is provided with a first metal electrode and a second metal electrode. The back side includes a first mesa in a groove, a second mesa, and a groove sidewall between them. A first metal electrode is disposed on the first mesa. A first-type semiconductor layer in the semiconductor layer sequence acts as a support layer. A distance from a bottom surface of the groove to a front side of the semiconductor layer sequence is not greater than 4 micrometers. On a horizontal projection plane of a longer side of the support layer, the semiconductor layer sequence is at least partially penetrated by the groove. The first metal electrode extends along the longer side of the support layer, and specifically extends from the groove sidewall to the second mesa.

### CROSS-REFERENCE TO RELATED APPLICATION

This application is a continuation of International Application No. PCT/CN2022/110617, filed Oct. 21, 2022, which is herein incorporated by reference in its entirety.

### TECHNICAL FIELD

The present disclosure relates to the field of semiconductor manufacturing technologies, and particularly to a micro light-emitting diode (micro-LED) and a display apparatus.

### BACKGROUND

A micro-LED (mLED) is currently a hot topic of research as a next-generation display light source. The mLED features a lower power consumption, a higher brightness, ultra-high resolution and color saturation, a faster response time, a lower energy consumption, and a longer lifespan. In addition, a power consumption of the mLED is only about 10% of a power consumption of a liquid crystal display (LCD) and 50% of a power consumption of an organic light-emitting diode (OLED). Compared with the OLED, which can also achieve self-emitting, the mLED offers much higher brightness and can achieve a higher pixel density resolution. These significant advantages of the mLED make it be a promising candidate to replace the OLED and the LCD, and become a light source for a next-generation display. However, the mLED is not yet mass-producible because there are still many technical challenges to overcome. One of key challenges is how to improve a transfer yield. The present disclosure aims to address this issue by proposing a feasible solution that can enable high-yield transfer of mLEDs.

### SUMMARY

In view of the fact that a substrate of a micro-LED needs to be removed and a semiconductor material of a semiconductor layer sequence acts a supporting function, when the semiconductor layer sequence is further thinned or removed, the micro-LED becomes very fragile. As a result, it is difficult to achieve higher transfer yield through conventional structures during mass transfer of micro-LEDs.

In a first aspect, an embodiment of the present disclosure provides a micro-LED. The micro-LED includes a semiconductor layer sequence. The semiconductor layer sequence has a front side and a back side opposite to the front side. The semiconductor layer sequence includes: a first-type semiconductor layer, a second-type semiconductor layer, and an active layer between the first-type semiconductor layer and the second-type semiconductor layer. The back side of the semiconductor layer sequence is provided with a groove, the groove penetrates through the second-type semiconductor layer and the active layer, and the first-type semiconductor layer is exposed through the groove. In order to expose the first-type semiconductor layer, a part of the first-type semiconductor layer is typically removed. A first metal electrode and a second metal electrode are disposed on the back side of the semiconductor layer sequence. The back side of the semiconductor layer sequence includes: a first mesa within the groove, a second mesa, and a groove sidewall located between the first mesa and the second mesa. The first metal electrode is disposed on the first mesa, and the second metal electrode is disposed on the second mesa. The first metal electrode is electrically connected to the first-type semiconductor layer. The second metal electrode is electrically connected to the second-type semiconductor layer. The first-type semiconductor layer acts as a support layer; from a top view direction of the front side, the support layer is rectangular. In a stacking direction from the first metal electrode to the semiconductor layer sequence, a distance from at least a part of a bottom surface of the groove to the front side of the semiconductor layer sequence is not greater than 4 micrometers, i.e., a thickness of the first-type semiconductor layer within the groove does not exceed 4 micrometers, for example, ranging from 1 micrometer to 4 micrometers. On a horizontal projection plane of a side surface of the support layer extending in an extending direction of a longer side of the support layer, the semiconductor layer sequence is at least partially penetrated by the groove. The first metal electrode extends in the extending direction of the longer side of the support layer, and the first metal electrode extends from the groove sidewall to the second mesa, so as to reinforce a stress concentration area where a thickness of the semiconductor layer sequence changes significantly. A dielectric passivation layer is disposed between the first metal electrode and the second mesa, as well as between the first metal electrode and the groove sidewall.

In an embodiment, from a horizontal projection plane of a side surface of the support layer extending in an extending direction of a shorter side of the support layer, a width of a coverage surface of the first metal electrode on the second mesa is greater than 20% of a length of the shorter side, so as to ensure sufficient holding strength.

In an embodiment, a length ratio of a longer side to a shorter side of the support layer is in a range of 1.5 to 5. The support layer is designed to have this elongated shape and provides a sufficient holding strength. When considering a minimum thickness of the support layer, and the length ratio of the longer side to the shorter side is less than 5, a breaking probability of the support layer under force is relatively lower. However, when the length ratio of the longer side to the shorter side of the support layer exceeds 5, the breaking probability significantly increases due to the increased moment of force.

In an embodiment, A manufacturing process of the micro-LED includes a substrate removal process, thereby exposing the front side of the semiconductor layer sequence. The micro-LED has no supporting substrate, and the front side of the semiconductor layer sequence is either the first-type semiconductor layer or an undoped semiconductor layer, with at least a portion of the front side of the semiconductor layer sequence being removed.

In an embodiment, the front side of the semiconductor layer sequence has a patterned or roughened surface.

In an embodiment, the aforementioned substrate removal process may lead to improvements in optical performance, such as control over the light pattern. However, it may also cause some damage or potential issues to a front side of the first-type semiconductor layer, i.e., cause some damage or potential issues to the support layer. The front side of the semiconductor layer sequence is covered with an insulating protective layer, and a front side of the insulating protective layer is exposed. A thickness of the insulating protective layer is in a range of 2000 angstroms (Å) to 10000 Å. The insulating protective layer provides support for the patterned or roughened surface, and provides a holding strength to the front side of the semiconductor layer sequence.

In an embodiment, a material of the insulating protective layer comprises at least one of silicon dioxide, silicon nitride, titanium oxide, or aluminum oxide.

In an embodiment, the micro-LED of the present disclosure is an LED chip with a dimension smaller than 100 micrometers×150 micrometers, which either has a support substrate or has no support substrate.

In an embodiment, the first metal electrode includes multiple metal layers, a first metal layer of the first metal electrode is in contact with the back side, a deformation modulus of the first metal layer is not less than 100 GPa, a thickness of the first metal layer is in a range of 30 Å to 1000 Å. The higher deformation modulus of the first metal layer ensures that the semiconductor layer sequence is not cut off when the semiconductor layer sequence is subjected to shear force moments.

In an embodiment, the first metal layer includes one of ruthenium, rhodium, or chromium.

In an embodiment, the first metal electrode includes multiple metal layers, a first metal layer of the first metal electrode is disposed on the back side of the semiconductor layer sequence, a deformation modulus of the first metal layer is not less than 100 GPa, a thickness of the first metal layer is in a range of 10 Å to 30 Å, the front side of the semiconductor layer sequence is covered with an insulating protective layer, and a thickness of the insulating protective layer is in a range of 2000 Å to 5000 Å. By employing a composite reinforcement design, the thickness of the first metal layer is reduced, thereby minimizing the absorption of radiation by the first metal layer.

In an embodiment, the first metal electrode sequentially includes a first metal layer, a second metal layer, and a third metal layer, the second metal layer is individually in direct contact with the first metal layer and the third metal layer, a deformation modulus of each of the first metal layer and the third metal layer is greater than a deformation modulus of the second metal layer, the deformation modulus of each of the first metal layer and the third metal layer is not less than 100 GPa, and a sum of thicknesses of the first metal layer and the third metal layer is in a range of 30 Å to 1000 Å. The first metal layer and the third metal layer together provide a holding strength.

In an embodiment, the third metal layer includes one of ruthenium, rhodium, or chromium.

In an embodiment, the second metal layer is a metal reflective layer, and a material of the second metal layer is aluminum or silver, which ensures the reliability of the micro-LED while enhancing the brightness of the micro-LED.

In an embodiment, the aforementioned soft metal, i.e., aluminum or silver is used as the metal reflective layer, and a thickness of the second metal layer is in a range of 10 Å and 2000 Å. Limiting the thickness of the second metal reflective layer is necessary, because if the thickness of the soft metal exceeds 2000 Å, the reliability of the micro-LED may be potentially reduced. Since the second metal layer is required to have a reflective property, a thickness less than 10 Å would struggle to provide an effective reflective contribution.

In an embodiment, on a top view projection plane of the back side, an area of the groove is 25% to 60% of an area of the first-type semiconductor layer. When the area of the groove is smaller than 60% of the area of the first-type semiconductor layer, a moment of force is relatively smaller, so there is virtually no breaking issue of the support layer during the transfer process, whereas, when the area of the groove is greater than 60% of the area of the first-type semiconductor layer, excessive loss of a light-emitting area is caused.

In an embodiment, the first metal electrode includes multiple metal layers, and a total thickness of metal layers with a deformation modulus of not less than 100 GPa of the multiple metal layers is in a range of 30 Å to 1000 Å, as such, the first metal electrode can provide a sufficient holding strength.

In an embodiment, a material of the semiconductor layer sequence is a gallium nitride series or an aluminum gallium indium phosphide series, and a thickness of the first-type semiconductor layer in the groove is less than 4 micrometers.

In an embodiment, a difference between an area of the second metal electrode on the second mesa and an area of a part on the second mesa of the first metal electrode is not greater than 30% of the area of the second mesa of the second metal electrode, so as to enhance the stability of a bonding force during encapsulation, reduce a shear force moment, and improve a transfer yield of micro-LEDs.

In a second aspect, an embodiment of the present disclosure provides another micro-LED. The micro-LED includes a semiconductor layer sequence. The semiconductor layer sequence has a front side and a back side opposite to the front side. The semiconductor layer sequence includes: a first-type semiconductor layer, a second-type semiconductor layer, and an active layer between the first-type semiconductor layer and the second-type semiconductor layer. The back side of the semiconductor layer sequence is provided with a groove. A first metal electrode and a second metal electrode are disposed on the back side of the semiconductor layer sequence. The back side of the semiconductor layer sequence includes: a first mesa within the groove, a second mesa, and a groove sidewall located between the first mesa and the second mesa. The groove penetrates through the second mesa to the first-type semiconductor layer, and a portion of the second-type semiconductor layer is removed. The first metal electrode is disposed on the first mesa, and the second metal electrode is disposed on the second mesa. The first metal electrode is electrically connected to the first-type semiconductor layer. The second metal electrode is electrically connected to the second-type semiconductor layer. The first-type semiconductor layer acts as a support layer; from a top view direction of the front side, the support layer is rectangular. In a stacking direction from the first metal electrode to the semiconductor layer sequence, a distance from at least a part of a bottom surface of the groove to the front side of the semiconductor layer sequence is not greater than 4 micrometers, i.e., a thickness of the first-type semiconductor layer within the groove does not exceed 4 micrometers, for example, ranging from 1 micrometer to 4 micrometers. On a top view projection plane of the back side, an area of the groove is 25% to 60% of an area of the first-type semiconductor layer. The first metal electrode extends in the extending direction of the longer side of the support layer, and the first metal electrode extends from the groove sidewall to the second mesa, so as to reinforce a stress concentration area where a thickness of the semiconductor layer sequence changes significantly. A dielectric passivation layer is disposed between the first metal electrode and the second mesa, as well as between the first metal electrode and the groove sidewall.

In a third aspect, an embodiment of the present disclosure provides a display apparatus, which includes a substrate, and any one of the micro-LEDs described above.

Beneficial effects of the present disclosure include, but are not limited to, enhancing the reliability of the micro-LED, reducing or avoiding the cutting off of the support layer, and improving an overall yield of the micro-LED.

### BRIEF DESCRIPTION OF DRAWINGS

Accompanying drawings are provided to further understand the present disclosure and are part of the specification. Together with embodiments of the present disclosure, the accompanying drawings are used to explain the present disclosure and do not limit the present disclosure. In addition, the accompanying drawings is descriptive and not drawn to scale.

FIG. 1 and FIG. 2 illustrate schematic structural diagrams of an existing transfer process.

FIG. 3 and FIG. 4 illustrate a schematic cross-sectional diagram and a schematic three-dimensional structural diagram of a micro-LED of a first embodiment of the present disclosure.

FIG. 5 illustrates a schematic cross-sectional diagram of a micro-LED of a second embodiment of the present disclosure.

FIG. 6 illustrates a schematic cross-sectional diagram of a micro-LED of a third embodiment of the present disclosure and an enlarged view of a first metal electrode.

FIG. 7 illustrates a schematic cross-sectional diagram of a first metal electrode stack of a fourth embodiment of the present disclosure.

FIG. 8 illustrates a schematic cross-sectional diagram of a first metal electrode stack of a fifth embodiment of the present disclosure.

FIG. 9 and FIG. 10 illustrate schematic cross-sectional diagrams of a micro-LED of a sixth embodiment of the present disclosure.

FIG. 11 illustrates a schematic cross-sectional diagram of a micro-LED of a seventh embodiment of the present disclosure.

### DESCRIPTION OF REFERENCE NUMERALS

100. micro-LED; 110. semiconductor layer sequence; 111. first-type semiconductor layer; 112. second-type semiconductor layer; 113. active layer; 120. support layer; 200. stamper; 310. first metal electrode; 311. first metal layer; 312. second metal layer; 313. third metal layer; 314. fourth metal layer; 331. platinum layer; 332. bonding metal layer; 320. second metal electrode; 400. dielectric passivation layer; 500. insulating protective layer; C1. fracture; D1, D2. length; G1. first groove; G2. second groove; L1. longer side; L2. shorter side; M1. first mesa; M2. second mesa; S1. first groove sidewall; PD1. horizontal projection plane of the longer side.

### DETAILED DESCRIPTION OF EMBODIMENTS

The following detailed description of the present disclosure will be provided in conjunction with the accompanying drawings and the embodiments of the present disclosure, so that a process of applying technical means to solve technical problems and achieve technical effects can be fully understood and implemented. It should be noted that as long as there is no conflict, various embodiments of the present disclosure and the various features within the embodiments can be combined with each other, and resulting technical solutions are all within the scope of protection of the present disclosure.

To better implement the technical solutions of the present disclosure, a transfer process involved in the present disclosure is described, and a brief description of an existing transfer process is provided.

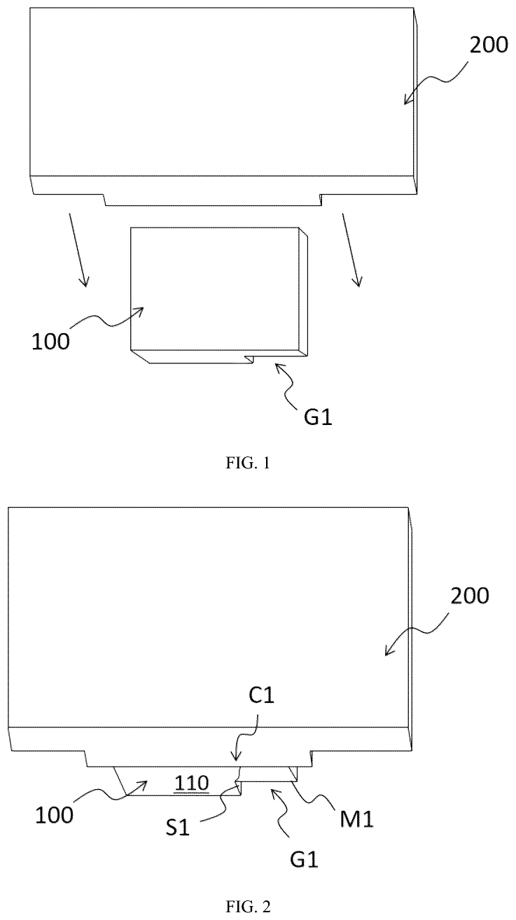

Referring to FIG. 1, in a transfer process of a conventional micro-LED, such as in a manufacturing process of a high-pixel display chip, a size of a micro-LED 100 is within 100 micrometers×150 micrometers. The manufacturing process involves stamping and imprinting, picking up, and placing by ultra-thin and/or small devices. The design of the present disclosure allows that microtransfer printing is achieved by select and apply these ultra-thin, fragile, and/or small devices without causing damage to the chip themselves.

A mass transfer method of microtransfer printing allows for deterministic assembly and integration of micro-scale and high-performance device arrays onto non-native substrates. In a simplest implementation, microtransfer printing is similar to using a rubber stamper to transfer fluid-based ink from a printing plate to paper. However, in the microtransfer printing, the “ink” consists of high-performance solid-state semiconductor devices, and the “paper” may be a substrate containing a circuit board, adhesive film, plastic, or other semiconductors. The microtransfer printing process utilizes a designed elastomer stamper 200 coupled with a high-precision control printing head to selectively pick up and print large arrays of micro-scale devices onto a non-native substrate.

Referring to FIG. 2, during the mass transfer process, there is a compression and printing of the micro-LED 100 by the stamper 200. When a first groove G1 exists on a side of the micro-LED 100 facing away from the stamper 200, for example, an N-type window layer of a semiconductor layer sequence 110 is provided with the first groove G1, especially when a side of the micro-LED 100 facing towards the stamper 200 is thinned, roughened, or pattern-etched and removed, the micro-LED 100 is prone to generate a fracture C1 at a connection between a sidewall S1 of the first groove G1 and a first mesa M1.

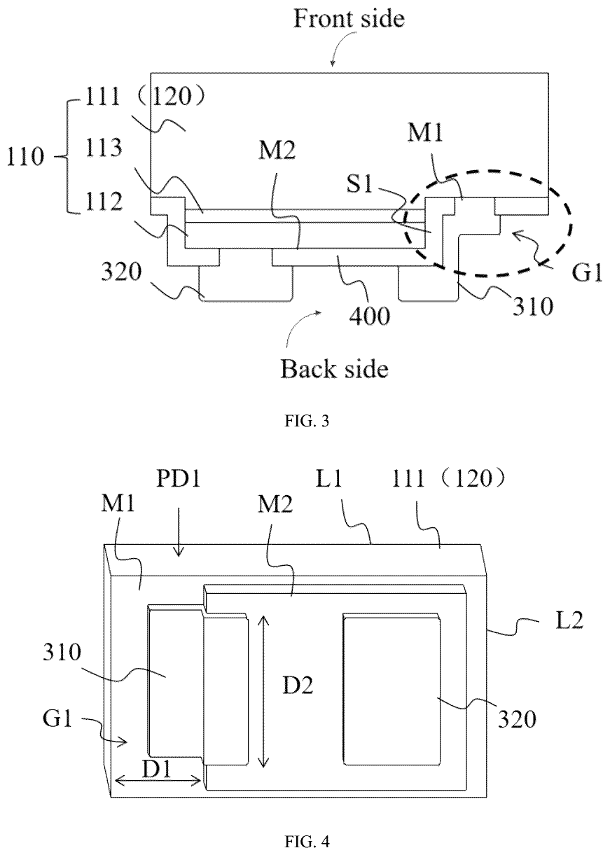

Referring to FIG. 3 and FIG. 4, a first embodiment of the present disclosure provides a micro-LED, which includes a semiconductor layer sequence 110. The semiconductor layer sequence 110 has a front side and a back side opposite to the front side. Specifically, an upper surface of a side of the semiconductor layer sequence 110 facing away from the first metal electrode 310 and the second metal electrode 320 is the front side, and a lower surface of a side of the semiconductor layer sequence 110 facing towards the first metal electrode 310 and the second metal electrode 320 is the back side. The semiconductor layer sequence 110 includes a first-type semiconductor layer 111, a second-type semiconductor layer 112, and an active layer 113 between the first-type semiconductor layer 111 and the second-type semiconductor layer 112. In this embodiment, a material of the semiconductor layer sequence 110 is a gallium nitride series or an aluminum gallium indium phosphide series. In a specific embodiment, the semiconductor layer sequence 110 generates light by recombining electrons produced by the first-type semiconductor layer 111 with holes produced by the second-type semiconductor layer 112. After a substrate removal process is performed, the front side of the semiconductor layer sequence 110 is exposed.

The back side of the semiconductor layer sequence 110 has a first groove G1 with a mesa structure. In this embodiment, the patterned first groove G1 is used to set a current injection window for injecting a current into the first-type semiconductor layer 111. The first groove G1 sequentially penetrates through the second-type semiconductor layer 112, the active layer 113, and a part of the first-type semiconductor layer 111, and the first-type semiconductor layer 111 is exposed by the first groove G1. Since the first-type semiconductor layer 111 has a relatively larger thickness, a part of the first-type semiconductor layer 111 can serve as a support layer 120. On a horizontal projection plane PD1 of a side surface of the support layer 120 extending in an extending direction of a longer side L1 of the support layer 120, the semiconductor layer sequence 110 is at least partially penetrated by the first groove G1. Specifically, on the horizontal projection plane PD1 of the side surface of the support layer 120 extending in the extending direction of the longer side L1 of the support layer 120, a length D1 of a penetrated region of the semiconductor layer sequence 110 by the first groove G1 is 25% to 60% of a length of the longer side L1. Since a large part of a side surface of the semiconductor layer sequence 110 is removed, it is more convenient for the design of the first metal electrode 310 in this embodiment.

The back side of the semiconductor layer sequence 110 is provided with the first metal electrode 310 and the second metal electrode 320, which are used for connection with external circuits. The back side of the semiconductor layer sequence 110 includes a first mesa M1 within the first groove G1, a second mesa M2, and a first groove sidewall S1 between the first mesa M1 and the second mesa M2. The first metal electrode 310 is disposed on the first mesa M1, and the first mesa M1 is located at a bottom surface of the first groove G1. The second metal electrode 320 is disposed on the second mesa M2. The first metal electrode 310 is directly connected to the first-type semiconductor layer 111. The second metal electrode 320 is electrically connected to the second-type semiconductor layer 112, for example, the second metal electrode 320 is connected to the second-type semiconductor layer 112 through a transparent current spreading layer (not labeled in FIG. 4).

The first-type semiconductor layer 111 serves as the support layer 120, and is used to provide support for the semiconductor layer sequence 110. From a top view projection direction of the front side, the support layer 120 is generally rectangular, and a length ratio of the longer side L1 to the shorter side L2 of the support layer 120 is in a range of 1.5 to 5. In a vertical direction, a distance from at least a part of the first groove G1 to the front side of the semiconductor layer sequence 110 is not greater than 4 micrometers. That is, a thickness of at least a part of the first-type semiconductor layer 111 within the first groove G1 is not greater than 4 micrometers. For example, the thickness of the part of the first-type semiconductor layer 111 within the first groove G1 is in a range of 1 micrometer to 4 micrometers. On a top view projection plane of the back side, an area of the first groove G1 is 25% to 60% of an area of the first-type semiconductor layer 111. Here, the area of the first groove G1 refers to an area of a region corresponding to the single first groove G1, excluding a boundary area of the second mesa M2.

The first metal electrode 310 extends in the extending direction of the longer side L1 of the support layer 120, specifically extending from the first groove sidewall S1 to the second mesa M2. The first metal electrode 310 includes multiple metal layers, and a total thickness of metal layers with a deformation modulus of not less than 100 GPa of the multiple metal layers is in a range of 30 Å to 1000 Å.

A dielectric passivation layer 400 is provided between the first metal electrode 310 and the second mesa M2, as well as between the first metal electrode 310 and the first groove sidewall S1. The dielectric passivation layer 400 electrically isolates the first metal electrode 310 from the second mesa M2. A material of the dielectric passivation layer 400 includes at least one of silicon dioxide, silicon nitride, or a distributed Bragg reflector (DBR). For example, if the material of the dielectric passivation layer 400 is the silicon dioxide, a thickness of the dielectric passivation layer 400 is between 1000 Å and 10000 Å, for isolating the first metal electrode 310 from the second mesa M2. From a projection plane of a side surface of the support layer 120 extending in an extending direction of the shorter side L2 of the support layer 120, a width D2 of the coverage area of the first metal electrode 310 on the second mesa M2 is greater than 20% of a length of the shorter side L2, for example, the width D2 of the coverage area is 20% to 90% of the length of the shorter side L2.

The first metal electrode 310 includes multiple metal layers. A first metal layer 311 of the first metal electrode 310 is in contact with the back side. A deformation modulus of the first metal layer 311 is not less than 100 GPa, and a thickness of the first metal layer 311 is between 30 Å and 1000 Å. The first metal layer 311 includes ate least one of ruthenium, rhodium, or chromium.

Referring to FIG. 5, in a second embodiment of the present disclosure, the front side of the semiconductor layer sequence 110 is the first-type semiconductor layer 111 or an undoped semiconductor layer, and at least a part of the front side of the semiconductor layer sequence 110 is removed.

The front side of the semiconductor layer sequence 110 has a patterned or roughened surface. For example, the commonly adopted methods for setting up a roughened surface to reduce total internal reflection and thereby increase the light emission from the front side include: using an etching solution to remove part of a semiconductor material on the front side of the semiconductor layer sequence 110, and forming a roughened second recess G2 on a surface of the semiconductor layer sequence 110. After roughening, in a vertical direction, there is a region in the first-type semiconductor layer 111 with a thickness not exceeding 4 micrometers, for example, a thickness of a region of the first-type semiconductor layer 111 at a junction between the first mesa M1 and the second mesa M2 is in a range of 1 micrometer to 4 micrometers.

The front side of the semiconductor layer sequence 110 is covered with an insulating protective layer 500, which is exposed. In this embodiment, the insulating protective layer 500 is fully exposed on the front side of the semiconductor layer sequence 110, and a thickness of the insulating protective layer 500 is between 2000 Å and 10000 Å. According to this embodiment, although the independent setting of the insulating protective layer 500 in the micro-LED can reduce the probability of fracture anomalies, it still cannot completely avoid fracture anomalies.

On the basis of covering the front side with the insulating protective layer 500, the first metal electrode 310 is reinforced in design. The first metal electrode 310 includes multiple metal layers. The first metal layer (not shown) of the first metal electrode 310 is in contact with the back side. The deformation modulus of the first metal layer is not less than 100 GPa, and a thickness of the first metal layer is between 10 Å and 30 Å. The front side of the semiconductor layer sequence 110 is covered with the insulating protective layer 500. The thickness of the insulating protective layer 500 covering the front side of the semiconductor layer sequence 110 is between 2000 Å and 10000 Å, which can reduce the thickness requirement of the first metal layer and enhance the flexibility of the electrode thickness design, for example, reducing the light absorption of the first metal layer.

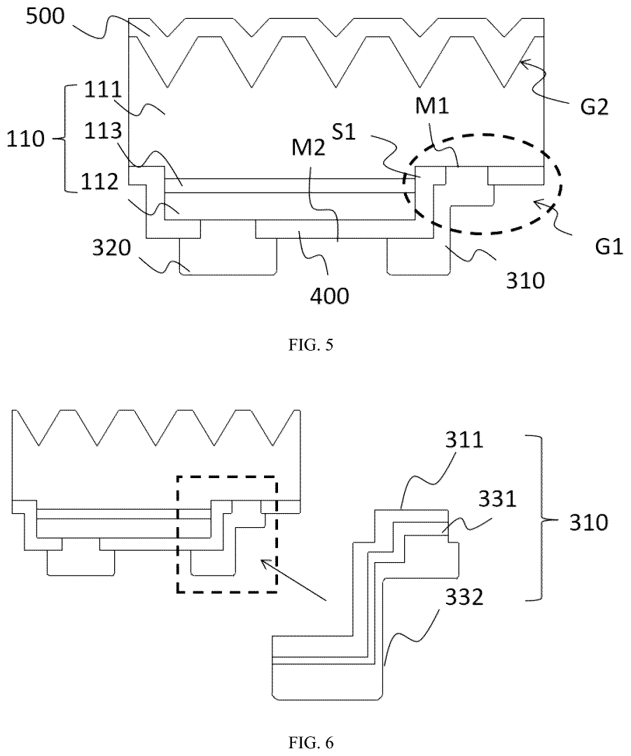

Referring to FIG. 6, in a third embodiment of the present disclosure, based on the first and second embodiments, the first metal electrode 310 is further designed to have a metal-layer stack structure. This embodiment mainly describes materials and relative positions of stacked layers of the metal-layer stack structure. The first metal electrode 310 includes a first metal layer 311 in contact with the back side of the semiconductor layer sequence. A platinum layer 331 and a bonding metal layer 332 are disposed on the first metal layer 311. A material of the bonding metal layer 332 includes gold. A thickness of the platinum layer 331 is between 300 Å and 1000 Å. Although a deformation modulus of the platinum layer 331 is slightly lower than that of the first metal layer 311, the platinum layer 331 can still provide reliable support with the above thickness. In this embodiment, a thickness of the platinum layer 331 is 500 Å.

In this embodiment, the first metal layer 311 extends in the extending direction of the longer side L1 of the support layer 120 (the first-type semiconductor layer), specifically extending from the first groove sidewall S1 to the second mesa M2. A deformation modulus of the first metal layer 311 is not less than 100 GPa, and a thickness of the first metal layer 311 is between 30 Å and 100 Å. In this embodiment, the thickness of the first metal layer 311 is 50 Å, the first metal layer 311 extends in the extending direction of the longer side L1 of the support layer 120, specifically extending from the first groove sidewall S1 to the second mesa M2. From a horizontal projection plane of a side surface of the support layer 120 extending in an extending direction of the shorter side L2 of the support layer 120, a width of a coverage area of the first metal layer 311 on the second mesa M2 is greater than 20% of a length of the shorter side L2.

On a horizontal projection plane PD1 of a side surface of the support layer 120 extending in an extending direction of a longer side L1 of the support layer 120, the semiconductor layer sequence 110 is at least partially penetrated by the first groove G1. Specifically, on the horizontal projection plane PD1 of the side surface of the support layer 120 extending in the extending direction of the longer side L1 of the support layer 120, a length D1 of a penetrated region of the semiconductor layer sequence 110 by the first groove G1 is 25% to 60% of a length of the longer side L1. Since a large part of a side surface of the semiconductor layer sequence 110 is removed, it is more convenient for the design of the first metal electrode 310 in this embodiment.

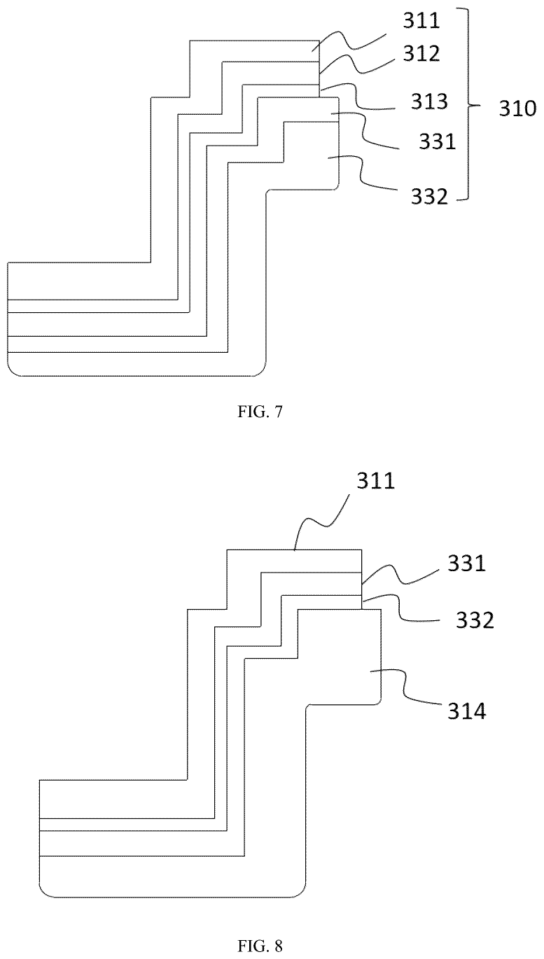

Referring to FIG. 7, in a fourth embodiment of the present disclosure, based on the first and second embodiments, the first metal electrode 310 is further designed to have a metal-layer stack structure. This embodiment mainly describes materials and relative positions of stacked layers of the metal-layer stack structure. The first metal electrode 310 sequentially includes a first metal layer 311, a second metal layer 312, and a third metal layer 313. From the manufacturing process, the second metal layer 312 is disposed between the first metal layer 311 and the third metal layer 313, and the second metal layer 312 is in direct contact with both the first metal layer 311 and the third metal layer 313. A deformation modulus of each of the first metal layer 311 and the third metal layer 313 is greater than that of the second metal layer 312. In terms of hardness, the deformation modulus of each of the first metal layer 311 and the third metal layer 313 is not less than 100 GPa. To ensure reliability, a sum of thicknesses of the first metal layer 311 and the third metal layer 313 is designed to be between 30 Å and 100 Å in this embodiment. The third metal layer 313 includes at least one of ruthenium, rhodium, or chromium. In this embodiment, the thickness of the first metal layer 311 is between 10 Å and 30 Å, and the thickness of the third metal layer 313 is between 20 Å and 70 Å.

In this embodiment, to provide the external quantum efficiency of the micro-LED, the second metal layer 312 is set as a metal reflective layer. A material of the second metal layer 312 is aluminum or silver, and a thickness of the second metal layer 312 is between 10 Å and 5000 Å.

Referring to FIG. 8, in a fifth embodiment of the present disclosure, based on the first and second embodiments, the first metal electrode 310 is further designed to have a metal-layer stack structure. This embodiment mainly describes materials and relative positions of stacked layers of the metal-layer stack structure. The first metal electrode 310 sequentially includes a first metal layer 311, a platinum layer 331, a bonding metal layer 332, and a fourth metal layer 314. The first metal layer 311 includes at least one of ruthenium, rhodium, or chromium, and a thickness of the first metal layer 311 is in a range of 40 Å to 60 Å. A material of the platinum layer 331 is platinum, and a thickness of the platinum layer 331 is in a range of 100 Å to 1000 Å. A material of the bonding metal layer 332 is gold, and a thickness of the bonding metal layer 332 is in a range of 100 Å to 1000 Å. The fourth metal layer 314 includes at least one of titanium, nickel, tin, silver, or copper.

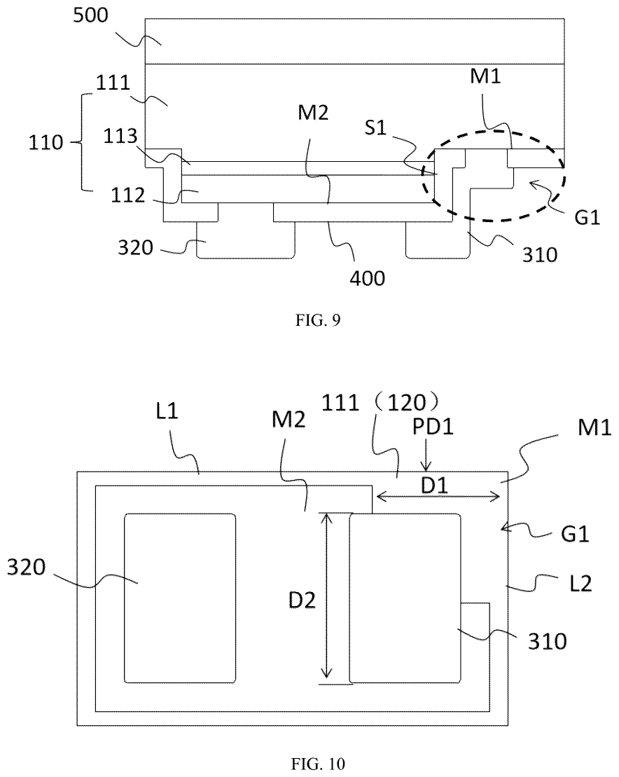

Referring to FIG. 9 and FIG. 10, in a sixth embodiment of the present disclosure, even though roughening is not performed, the present disclosure is applicable to designs with a thinner support layer 120. In existing chip technologies, a thickness of the support layer 120 is typically greater than 4 micrometers. For example, in conventional-sized chips using sapphire, a thickness of the sapphire is usually greater than 50 micrometers. As an opposite design, this embodiment does not use a support substrate. Since the support substrate is removed and the semiconductor layer sequence 110 is penetrated from a side of a projection plane of the longer side L1, there are a stress concentration area and a stress defect area throughout the semiconductor layer sequence 110. Specifically, stress defects exist at a junction between the first mesa M1 and the second mesa M2, while other area is the stress concentration area. In this embodiment, a thickness of the first-type semiconductor layer 111 corresponding to the first mesa M1 is in a range of 1 micrometer to 4 micrometers. The semiconductor layer sequence 110 is at least partially penetrated by the first groove G1. Specifically, on the horizontal projection plane PD1 of the side surface of the support layer 120 extending in the extending direction of the longer side L1 of the support layer 120, a length D1 of a penetrated region of the semiconductor layer sequence 110 by the first groove G1 is 25% to 60% of a length of the longer side L1. Since a large part of a side surface of the semiconductor layer sequence 110 is removed, it is more convenient for the design of the first metal electrode 310 in this embodiment. Even if the front side of the first-type semiconductor layer 111 is not roughened or patterned, it may still break under pressure, resulting in poor overall structural stability.

In this embodiment, an opening of the first groove does not completely penetrate the horizontal projection plane of the longer side, a length of the first groove G1 along the shorter side L2 is 30% to 80% of a length of the first groove G1 along the longer side L1. However, a thickness of the support layer 120 is further reduced to below 3 micrometers. The first metal electrode 310 extends in the extending direction of the longer side L1 of the support layer 120, specifically extending from the first groove sidewall S1 to the second mesa M2. The first metal electrode 310 includes multiple metal layers, and a total thickness of metal layers with a deformation modulus of not less than 100 GPa of the multiple metal layers is in a range of 30 Å to 1000 Å.

In another implementation of this embodiment, the first metal electrode 310 extends in the extending direction of the longer side L1 of the support layer 120, specifically extending from the first groove sidewall S1 to the second mesa M2. The first metal electrode 310 includes multiple metal layers. A first metal layer 311 of the first metal electrode 310 is in contact with the back side. A deformation modulus of the first metal layer 311 is not less than 100 GPa, and a thickness of the first metal layer 311 is between 30 Å and 1000 Å. The first metal layer 311 includes ate least one of ruthenium, rhodium, or chromium.

In another implementation of this embodiment, the first metal electrode 310 sequentially includes a first metal layer 311, a second metal layer 312, and a third metal layer 313. From the manufacturing process, the second metal layer 312 is disposed between the first metal layer 311 and the third metal layer 313, and the second metal layer 312 is in direct contact with both the first metal layer 311 and the third metal layer 313. A deformation modulus of each of the first metal layer 311 and the third metal layer 313 is greater than that of the second metal layer 312. In terms of hardness, the deformation modulus of each of the first metal layer 311 and the third metal layer 313 is not less than 100 GPa. To ensure reliability, a sum of thicknesses of the first metal layer 311 and the third metal layer 313 is designed to be between 30 Å and 100 Å in this embodiment.

In this embodiment, any of the implementations from first through fifth embodiments, except for the roughening of the front side, are adopted, such as the design of the first metal electrode 310 and/or the insulating protective layer 500, to reinforce the structure itself. Taking the design of the insulating protective layer 500 as an example, a thickness of the insulating protective layer 500 is in a range of 2000 Å to 5000 Å, which can reduce the thickness requirement of the first metal layer 311 and enhance the flexibility of the electrode thickness design, for example, reducing the light absorption of the first metal layer 311. Alternatively, the thickness of the insulating protective layer 500 may be designed to be in a range of 5000 Å to 10000 Å, so that the design of the first metal layer 311 is not relied upon, and a soft metal can be used in the first metal layer 311 to improve the structural strength of the chip.

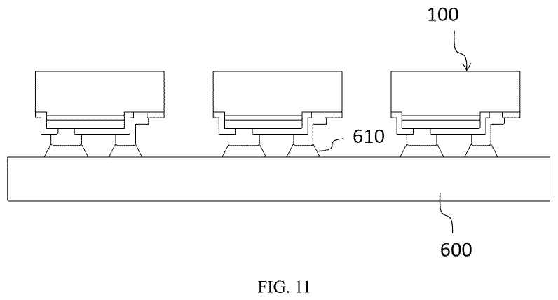

Referring to FIG. 11, in a seventh embodiment of the present disclosure, a display apparatus is proposed, which includes a substrate 600 and multiple micro-LEDs 100. The substrate 600 and the multiple micro-LEDs 100 are connected through wires or conductive pads 610. Each of the micro-LEDs 100 are any one micro-LED of the aforementioned embodiments.

The above descriptions are merely the illustrated embodiments of the present disclosure and are not intended to limit the present disclosure. Any modifications, equivalent substitutions, and improvements, made within the spirit and principles of the present disclosure are intended to be included within the scope of protection of the present disclosure.

What is claimed is:

1. A micro light-emitting diode (micro-LED), comprising a semiconductor layer sequence, wherein the semiconductor layer sequence has a front side and a back side opposite to the front side, the semiconductor layer sequence comprises: a first-type semiconductor layer, a second-type semiconductor layer, and an active layer between the first-type semiconductor layer and the second-type semiconductor layer, the back side of the semiconductor layer sequence is provided with a groove, the groove penetrates through the second-type semiconductor layer and the active layer, and the first-type semiconductor layer is exposed through the groove; a first metal electrode and a second metal electrode are disposed on the back side of the semiconductor layer sequence; the back side of the semiconductor layer sequence comprises: a first mesa within the groove, a second mesa, and a groove sidewall located between the first mesa and the second mesa; the first metal electrode is disposed on the first mesa, and the second metal electrode is disposed on the second mesa; the first metal electrode is electrically connected to the first-type semiconductor layer; and the second metal electrode is electrically connected to the second-type semiconductor layer; and
wherein the first-type semiconductor layer acts as a support layer; from a top view direction of the front side, the support layer is rectangular; in a stacking direction from the first metal electrode to the semiconductor layer sequence, a distance from at least a part of a bottom surface of the groove to the front side of the semiconductor layer sequence is not greater than 4 micrometers; on a horizontal projection plane of a side surface of the support layer extending in an extending direction of a longer side of the support layer, the semiconductor layer sequence is at least partially penetrated by the groove; the first metal electrode extends in the extending direction of the longer side of the support layer, and the first metal electrode extends from the groove sidewall to the second mesa; and a dielectric passivation layer is disposed between the first metal electrode and the second mesa, as well as between the first metal electrode and the groove sidewall.

2. The micro-LED as claimed in claim 1, wherein from a horizontal projection plane of a side surface of the support layer extending in an extending direction of a shorter side of the support layer, a width of a coverage surface of the first metal electrode on the second mesa is greater than 20% of a length of the shorter side.

3. The micro-LED as claimed in claim 2, wherein the width of the coverage surface of the first metal electrode on the second mesa is greater than 20% of the length of the shorter side and less than 90% of the length of the shorter side.

4. The micro-LED as claimed in claim 1, wherein a ratio of a length of the longer side of the support layer to a length of a shorter side of the support layer is in a range of 1.5 to 5.

5. The micro-LED as claimed in claim 1, wherein after a substrate removal process is performed, the front side of the semiconductor layer sequence is exposed, the front side of the semiconductor layer sequence is the first-type semiconductor layer or an undoped semiconductor layer, and at least a part of the front side of the semiconductor layer sequence is removed.

6. The micro-LED as claimed in claim 5, wherein the front side of the semiconductor layer sequence has a patterned or roughened surface.

7. The micro-LED as claimed in claim 1, wherein the front side of the semiconductor layer sequence is covered with an insulating protective layer, a front side of the insulating protective layer is exposed, and a thickness of the insulating protective layer is in a range of 2000 angstroms (Å) to 10000 Å.

8. The micro-LED as claimed in claim 7, wherein a material of the insulating protective layer comprises at least one of silicon dioxide, silicon nitride, titanium oxide, or aluminum oxide.

9. The micro-LED as claimed in claim 1, wherein a size of the micro-LED is within 100 micrometers×150 micrometers.

10. The micro-LED as claimed in claim 1, wherein the first metal electrode comprises multiple metal layers, a first metal layer of the first metal electrode is in contact with the back side, a deformation modulus of the first metal layer is not less than 100 GPa, a thickness of the first metal layer is in a range of 30 Å to 1000 Å, and the first metal layer comprises one of ruthenium, rhodium, or chromium.

11. The micro-LED as claimed in claim 1, wherein the first metal electrode comprises multiple metal layers, a first metal layer of the first metal electrode is disposed on the back side of the semiconductor layer sequence, a deformation modulus of the first metal layer is not less than 100 GPa, a thickness of the first metal layer is in a range of 10 Å to 30 Å, the front side of the semiconductor layer sequence is covered with an insulating protective layer, and a thickness of the insulating protective layer is in a range of 2000 Å to 10000 Å.

12. The micro-LED as claimed in claim 1, wherein the first metal electrode sequentially comprises a first metal layer, a second metal layer, and a third metal layer, the second metal layer is individually in direct contact with the first metal layer and the third metal layer, a deformation modulus of each of the first metal layer and the third metal layer is greater than a deformation modulus of the second metal layer, the deformation modulus of each of the first metal layer and the third metal layer is not less than 100 GPa, and a sum of thicknesses of the first metal layer and the third metal layer is in a range of 30 Å to 1000 Å.

13. The micro-LED as claimed in claim 12, wherein the second metal layer is a metal reflective layer, a material of the second metal layer is aluminum or silver, and a material of the third metal layer is one of ruthenium, rhodium, or chromium.

14. The micro-LED as claimed in claim 13, wherein a thickness of the second metal layer is in a range of 10 Å to 2000 Å.

15. The micro-LED as claimed in claim 1, wherein on a top view projection plane of the back side, an area of the groove is 25% to 60% of an area of the first-type semiconductor layer.

16. The micro-LED as claimed in claim 1, wherein the first metal electrode comprises multiple metal layers, and a total thickness of metal layers with a deformation modulus of not less than 100 GPa of the multiple metal layers is in a range of 30 Å to 1000 Å.

17. The micro-LED as claimed in claim 1, wherein a material of the semiconductor layer sequence is a gallium nitride series or an aluminum gallium indium phosphide series, and a thickness of at least a part of the first-type semiconductor layer in the groove is in a range of 1 micrometer to 4 micrometers.

18. The micro-LED as claimed in claim 1, wherein a difference between an area of the second metal electrode on the second mesa and an area of a part on the second mesa of the first metal electrode is not greater than 30% of the area of the second mesa of the second metal electrode.

19. The micro-LED as claimed in claim 1, wherein on the horizontal projection plane of the side surface of the support layer extending in the extending direction of the longer side of the support layer, a length of a penetrating region of the semiconductor layer sequence is 25% to 60% of a length of the longer side of the support layer.

20. A display apparatus, comprising: a substrate and the micro-LED as claimed in claim 1.
